(19) United States
(12) Patent Application Publication
(10) Pub. No.: US 2026/0121681 A1
(43) Pub. Date: Apr. 30, 2026

(54) RADIO FREQUENCY MODULE

(71) Applicant: Murata Manufacturing Co., Ltd., Nagaokakyo-shi (JP)

(72) Inventors: Yoshiki NAKANISHI, Nagaokakyo-shi (JP); Ryusuke YAMAGUCHI, Nagaokakyo-shi (JP); Hiroki KISE, Nagaokakyo-shi (JP); Yusuke OKAJIMA, Nagaokakyo-shi (JP); Michiharu YOKOYAMA, Nagaokakyo-shi (JP)

(73) Assignee: Murata Manufacturing Co., Ltd., Nagaokakyo-shi (JP)

(21) Appl. No.: 19/433,115

(22) Filed: Dec. 26, 2025

Related U.S. Application Data
(63) Continuation of application No. PCT/JP2024/009759, filed on Mar. 13, 2024.

(30) Foreign Application Priority Data
Jun. 30, 2023 (JP) 2023-108293

(51) Int. Cl. H04B 1/40; H05K 1/02; H05K 3/30

(52) U.S. Cl. CPC H04B 1/40; H05K 1/024; H05K 3/30

(57) ABSTRACT

A radio frequency module includes a substrate having major surfaces, a SiP module, a connector, first and second resins. The SiP module is mounted on the major surface and feeds the radiating element with a radio frequency signal. The connector is mounted on the major surface and is spaced from the SiP module in a first direction along a longer side. The first resin is between the dielectric substrate and the SiP module. The second resin is in a region between the SiP module and the connector and covers a side surface of the SiP module facing the connector. When the second resin has a first length from the SiP module to an end of the resin in the first direction and a second length is between the SiP module and the connector, the first length is equal to or larger than one half of the second length.

### CROSS-REFERENCE TO RELATED APPLICATIONS

The present application is a continuation of International Application No. PCT/JP2024/009759, filed Mar. 13, 2024, which claims priority to Japanese patent application JP 2023-108293, filed Jun. 30, 2023, the entire contents of each of which being incorporated herein by reference.

### TECHNICAL FIELD

The present disclosure relates to a radio frequency module, and more specifically to a technique used to prevent an electronic circuit from peeling off in a radio frequency module having the electronic circuit disposed on a substrate.

### BACKGROUND ART

Japanese Patent Laid-Open No. 2020-174172 (PTL 1) discloses an electronic element module having electronic elements such as a passive element and an active element and a connector. The electronic elements are disposed on one major surface of a rectangular substrate with an antenna disposed thereon/therein. The connector is disposed on the major surface at a side closer to an end for connection to another device of a mounting substrate or the like.

### CITATION LIST

### Patent Literature

PTL 1: Japanese Patent Laid-Open No. 2020-174172

### SUMMARY

### Technical Problems

The electronic element module configured as described above has the electronic elements spaced from the connector. When the electronic element module is connected to another device of a mounting substrate or the like using the connector, the connector is inserted, and the substrate of the electronic element module receives force. When inserting the connector, with the space between the electronic elements and the connector, the substrate is deflected with the connector acting as a support, and a tensile stress acts between the electronic elements and the substrate. This may peel the electronic elements off the substrate.

The present disclosure has been made to solve such a problem, and contemplates preventing an electronic circuit from peeling off when incorporating a radio frequency module in which the electronic circuit is disposed on a substrate.

### Solutions to Problems

According to the present disclosure, a radio frequency module is configured to feed a radiating element with a radio frequency signal. The radio frequency module comprises a dielectric substrate in the form of a flat plate, an electronic circuit, a connector, a first resin, and a second resin. The dielectric substrate has a first surface and a second surface. The electronic circuit is mounted on the second surface of the dielectric substrate and configured to feed the radiating element with a radio frequency signal. The connector is mounted on the second surface of the dielectric substrate and connectable to an external device. When viewed in a plan view in a direction along a normal to the dielectric substrate, the dielectric substrate is generally in the form of a rectangle having a longer side and a shorter side. The connector is spaced from the electronic circuit in a first direction along the longer side. The first resin is disposed between the dielectric substrate and the electronic circuit. The second resin is disposed on the second surface in a region between the electronic circuit and the connector and covers a side surface of the electronic circuit facing the connector. When the second resin has a first length from the electronic circuit to an end of the second resin in the first direction and a distance between the electronic circuit and the connector is represented as a second length, the first length is equal to or larger than one half of the second length.

### Advantageous Effects

The presently disclosed radio frequency module has a first resin disposed between a dielectric substrate and an electronic circuit, and a second resin disposed so as to cover a large area of a region on the dielectric substrate between the electronic circuit and a connector. Such a configuration can reduce stress acting between the electronic circuit and the dielectric substrate in incorporating the radio frequency module, and thus prevent peeling of the electronic circuit.

### BRIEF DESCRIPTION OF DRAWINGS

FIG. 1 is a block diagram of a communication device with a radio frequency module applied thereto according to a first embodiment.

FIG. 2 is a plan view of the radio frequency module according to the first embodiment.

FIG. 3 is a cross-sectional perspective view taken along a line III-III of the radio frequency module in FIG. 2.

FIG. 4 is a cross-sectional perspective view taken along a line IV-IV of the radio frequency module in FIG. 2.

FIG. 5 is a cross-sectional perspective view of a radio frequency module according to a first variation.

FIG. 6 is a diagram for illustrating deflection when the radio frequency module receives force.

FIG. 7 is a diagram for illustrating amounts of deflection depending on differences in dimension of a fillet.

FIG. 8 is a cross-sectional perspective view of a radio frequency module according to a second variation.

FIG. 9 is a plan view of a radio frequency module according to a second embodiment.

FIG. 10 is a cross-sectional perspective view taken along a line X-X of the radio frequency module in FIG. 9.

FIG. 11 is a plan view of a radio frequency module according to a third variation.

FIG. 12 is a cross-sectional perspective view taken along a line XII-XII of the radio frequency module in FIG. 11.

FIG. 13 is a diagram for illustrating a first example of a process for manufacturing a radio frequency module.

FIG. 14 is a diagram for illustrating a second example of a process for manufacturing a radio frequency module.

### DESCRIPTION OF EMBODIMENTS

Hereinafter, embodiments of the present disclosure will be described in detail with reference to the drawings. In the figures, identical or equivalent components are identically denoted and will not be described repeatedly.

### First Embodiment

### (Basic Configuration of Communication Device)

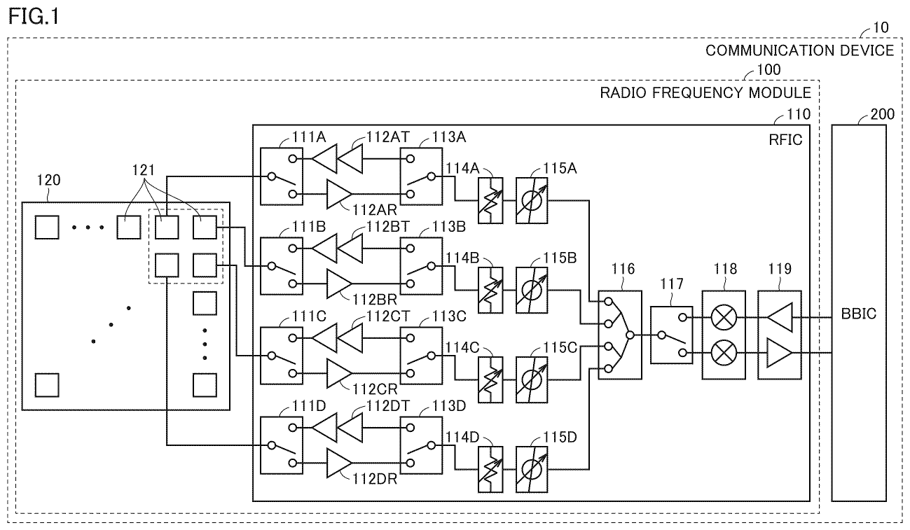

FIG. 1 is a block diagram of an example of a communication device 10 with a radio frequency module 100 applied thereto according to a first embodiment. Communication device 10 is, for example, a mobile phone, a smartphone, a tablet or a similar mobile terminal, a personal computer comprising a communication function, or the like.

Referring to FIG. 1, communication device 10 comprises radio frequency module 100, and a BBIC 200 constituting a baseband signal processing circuit. Radio frequency module 100 comprises an RFIC 110 that is an example of a feeder circuit, and an antenna device 120. Communication device 10 up-converts, to a radio frequency signal, a signal transmitted from BBIC 200 to radio frequency module 100 and radiates the radio frequency signal from antenna device 120. The communication device also down-converts a radio frequency signal received by antenna device 120 and processes the signal in BBIC 200.

Antenna device 120 shown in FIG. 1 has radiating elements 121 disposed in a two-dimensional array. Radiating element 121 receives a radio frequency signal from RFIC 110. For the sake of illustration, FIG. 1 only shows a configuration corresponding to four radiating elements 121 of a plurality of radiating elements 121 constituting antenna device 120, and does not show a configuration corresponding to other radiating elements 121 having a similar configuration. Antenna device 120 may not necessarily be a two-dimensional array, and a single radiating element 121 may form antenna device 120. Alternatively, the antenna device may be a one-dimensional array composed of a plurality of radiating elements 121 disposed in a single row. In the present embodiment, radiating element 121 is a patch antenna in the form of a generally square flat plate. Radiating element 121 is not limited in shape to be generally square, and may be rectangular, polygonal, round, elliptical, or the like.

RFIC 110 includes switches 111A-111D, 113A-113D and 117, power amplifiers 112AT-112DT, low noise amplifiers 112AR-112DR, attenuators 114A-114D, phase shifters 115A-115D, a signal combining/dividing device 116, a mixer 118, and an amplifier circuit 119.

When transmitting a radio frequency signal, switches 111A-111D and 113A-113D are switched to the side of power amplifiers 112AT-112DT, and switch 117 is connected to a transmitting amplifier of amplifier circuit 119. When receiving a radio frequency signal, switches 111A-111D and 113A-113D are switched to the side of low-noise amplifiers 112AR-112DR, and switch 117 is connected to a receiving amplifier of amplifier circuit 119.

A signal transmitted from BBIC 200 is amplified by amplifier circuit 119 and up-converted in mixer 118. The up-converted radio frequency signal, or a transmission signal, is divided by signal combining/dividing device 116 into four waves, which pass through respective signal paths and are fed to respective different radiating elements 121. Phase shifters 115A-115D are each disposed on a signal path and has a phase shifting degree individually adjusted to adjust antenna device 120 in directivity. Attenuators 114A-114D are adjusted to adjust a gain of a radio frequency signal to be radiated from each radiating element 121.

Radiating element 121 receives a radio frequency signal, and the received signal is transmitted to RFIC 110, passes through a respective one of four different signal paths, and is combined in signal combining/dividing device 116. The received, combined signal is down-converted in mixer 118, amplified by amplifier circuit 119, and transmitted to BBIC 200.

RFIC 110 is provided for example as a single-chip integrated circuit component including the above-described circuit configuration. Alternatively, for devices in RFIC 110 associated with each radiating element 121 (i.e., a switch, a power amplifier, a low noise amplifier, an attenuator, and a phase shifter), it may be provided as a single-chip integrated circuit component for each radiating element 121 associated therewith.

### (Configuration of Radio Frequency Module)

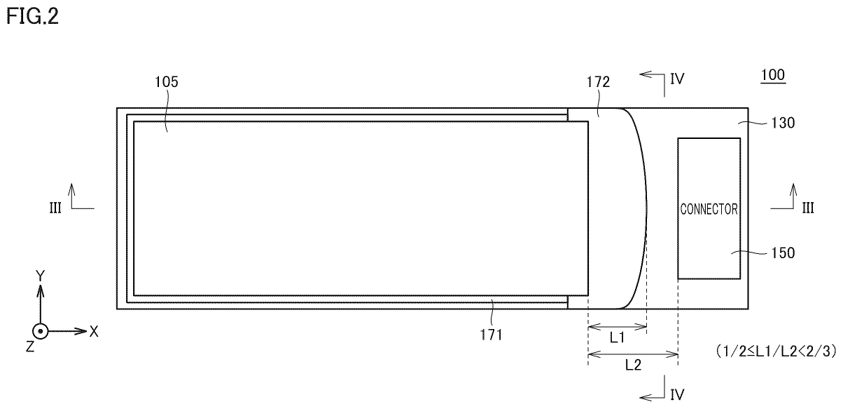

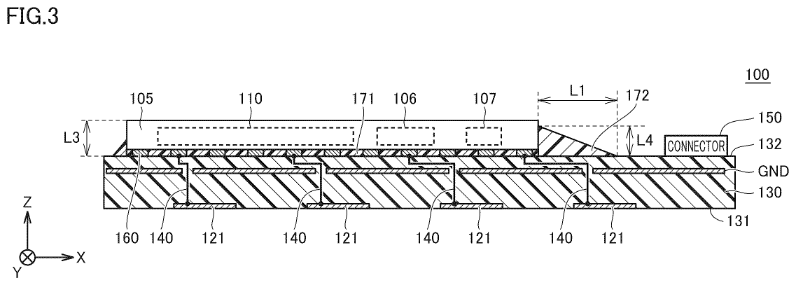

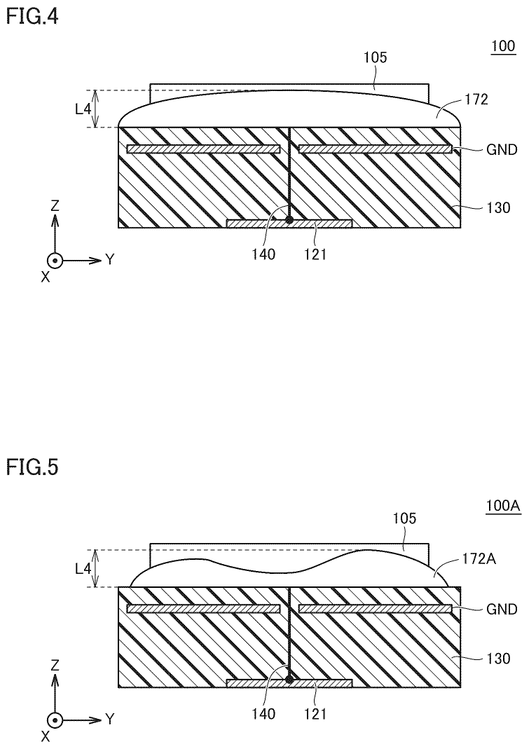

Hereinafter, a configuration of radio frequency module 100 according to the first embodiment will be described in detail with reference to FIGS. 2 to 4. FIG. 2 is a plan view of radio frequency module 100. FIG. 3 is a cross-sectional perspective view taken along a line III-III of the radio frequency module 100 in FIG. 2. FIG. 4 is a cross-sectional perspective view taken along a line IV-IV of the radio frequency module in FIG. 2. As shown in FIGS. 2 to 4, radio frequency module 100 has a thickness in a direction along the Z-axis, and a plane perpendicular to the direction along the Z-axis is defined by the X-axis and the Y-axis. Furthermore, in each figure, a positive direction along the Z axis may be referred to as an upper side, and a negative direction along the Z axis may be referred to as a lower side.

Referring to FIGS. 2 to 4, radio frequency module 100 comprises in addition to radiating element 121, a SiP (System in Package) module 105 including RFIC 110, a dielectric substrate 130, a ground electrode GND, a feed line 140, and a connector 150.

SiP module 105 is a circuit having, in addition to RFIC 110, a PMIC (power management integrated circuit) 106 and another electronic element 107 such as a power inductor, which are disposed and molded on a single substrate. SiP module 105 corresponds to an “electronic circuit” in the present disclosure.

Dielectric substrate 130 is, for example, a multilayer resin substrate formed by depositing a plurality of resin layers made of epoxy, polyimide or a similar resin, a multilayer resin substrate formed by depositing a plurality of resin layers made of a liquid crystal polymer (LCP) having a lower dielectric constant, or a multilayer resin substrate formed by depositing a plurality of resin layers made of a fluorine-based resin. Dielectric substrate 130 may not necessarily have a multilayer structure, and may be a substrate of a single layer.

Dielectric substrate 130 is generally in the form of a rectangle in a plan view from a normal direction (or the direction along the Z-axis). In the present specification, dielectric substrate 130 has a longer side in the direction along the X axis and a shorter side in the direction along the Y axis. Ground electrode GND is provided throughout a layer internal to dielectric substrate 130 and closer to an upper surface 132 of the dielectric substrate (a surface in the positive direction along the Z-axis). Radiating element 121 is provided at a side closer to a lower surface 131 of dielectric substrate 130 (a surface in the negative direction along the Z axis).

Radiating element 121 faces ground electrode GND. In the example of FIG. 3, four radiating elements 121 are spaced from one another in the direction along the X-axis and thus disposed in a row. Radiating element 121 may be exposed at a surface of dielectric substrate 130 or may be disposed in a layer internal to dielectric substrate 130.

SiP module 105 is mounted on upper surface 132 of dielectric substrate 130 via solder bumps 160. Furthermore, connector 150 is disposed on upper surface 132 of dielectric substrate 130 at an end in the positive direction along the X axis to connect radio frequency module 100 to another device of a mounting substrate or the like. Connector 150 is spaced from SiP module 105 in the positive direction along the X axis.

Radiating element 121 receives a radio frequency signal transmitted from SiP module 105 via feed line 140. Feed line 140 extends from solder bump 160 used to mount SiP module 105, and penetrates ground electrode GND and is connected to a feeding point of each radiating element 121.

A resin 171 is disposed between dielectric substrate 130 and SiP module 105 as underfill to fill a gap therebetween. Resin 171 is, for example, a thermosetting resin such as epoxy. Resin 171 may for example contain a filler such as silica particles. Resin 171 is used to prevent intrusion of foreign matters or the like between dielectric substrate 130 and SiP module 105, and also enhance strength of connection between dielectric substrate 130 and SiP module 105.

Furthermore, radio frequency module 100 has a resin 172 disposed on upper surface 132 of dielectric substrate 130 in a region between SiP module 105 and connector 150. Resin 172 is disposed so as to cover a side surface of SiP module 105 facing connector 150, and upper surface 132 of dielectric substrate 130. That is, resin 172 functions as a fillet. Resin 172 is also a thermosetting resin as well as resin 171. Resin 171 and resin 172 may be identical or different resins. As well as resin 171, resin 172 may also contain a filler. The state of a filler contained in resin 171 is identical to or different from that is contained in resin 172. A state of a filler contained in a resin indicates a containing condition of the filler. The condition includes the filler's content, shape, material, and/or the like. As will be described hereinafter, resin 172 is used to prevent SiP module 105 from having an end in the positive direction along the X axis peeled off dielectric substrate 130.

In the direction along the X-axis, resin 172 has an end extending to a position which is closer to connector 150 than the position of one half of a distance L2 between SiP module 105 and connector 150. More specifically, when L1 represents a distance from an end face of SiP module 105 to the end of resin 172, resin 172 extends to such a position that a ratio of L1 to L2 is ½≤L1/L2<⅔.

In the direction along the Y-axis, resin 172 extends to the ends along the longer sides of dielectric substrate 130. An end of the resin in the direction along the Y-axis does not necessarily reach the longer sides of dielectric substrate 130, as shown in FIG. 5 showing a first variation showing a radio frequency module 100A with a resin 172A. That is, resin 172 extends to a position where the resin does not extend beyond the longer sides of dielectric substrate 130.

An end position of resin 172 may be defined with reference to a height of SiP module 105. In that case, when a maximum height of SiP module 105 from upper surface 132 is defined as L3, the distance L1 to the position of the end of resin 172 is to be larger than L3 times 1.0 and smaller than L3 times 1.4 (i.e., 1.0<L1/L3<1.4).

Furthermore, when a maximum height of a portion of resin 172 in contact with SiP module 150 from upper surface 132 is defined as L4, the distance L1 to the position of the end of resin 172 is to be larger than L4 times 1.0 and smaller than L4 times 7.0 (i.e., 1.0<L1/L4<7.0).

The radio frequency module as described above is connected to an external device at the portion of the connector. The SiP module is spaced from the connector, and when the radio frequency module is connected to another device of a mounting substrate or the like using the connector, the connector is inserted, and this exerts force to the dielectric substrate of the radio frequency module. When inserting the connector, with the space between the SiP module and the connector, the substrate is deflected with the connector acting as a support, and a tensile stress acts between the SiP module and the dielectric substrate. This may peel the SiP module off the dielectric substrate.

Accordingly, in the present embodiment, a resin is applied to form a fillet in a region between the SiP module and the connector on a side closer to the SiP module to reduce a deflection amount of the dielectric substrate, and hence prevent peeling of the SiP module off the dielectric substrate.

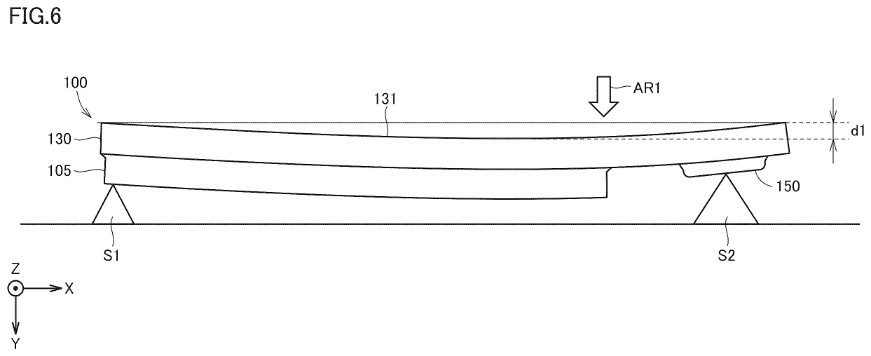

FIG. 6 schematically illustrates deflection when radio frequency module 100 receives force. A simulation is performed for an amount of deflection d1 caused when a force is applied to dielectric substrate 130 at lower surface 131, as indicated by an arrow AR1, while an end of dielectric substrate 130 in the negative direction along the X-axis and connector 150 are supported by supporting points S1 and S2, respectively.

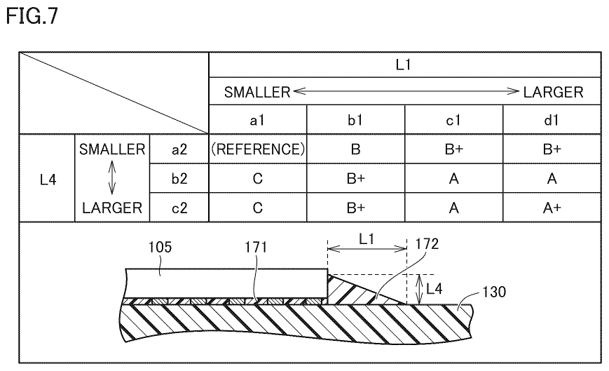

FIG. 7 is a diagram for illustrating an amount of deflection depending on a difference in dimension of a fillet of resin 172. The figure shows variations of the deflection amount when a dimension L1 is varied in an ascending order in four stages of a1, b1, c1 and d1 and a dimension L4 is varied in an ascending order in three stages of a2, b2 and c2, L1 being a dimension in the direction along the X-axis, L4 being a dimension in the direction along the Z-axis. More specifically, a deflection amount for L1=a1 and L4=a2 serves as a reference, and a reduced degree of the deflection amount in each case (that is, an improved degree of deformation of a product) is indicated by a rank A, B, or C. The rank B indicates a larger improved degree of deformation than that of the rank C and the rank A indicates a further larger improved degree of deformation. Furthermore, a rank with “+” indicates a larger improved degree of deformation than that of the same rank without “+”.

As shown in FIG. 7, it can be seen that as to both of L1 and L4, lager dimension achieves larger reduced degree and thus prevents deflection. The reduction in deflection can reduce stress caused between SiP module 105 and dielectric substrate 130, and thus prevent peeling of SiP module 105 off dielectric substrate 130.

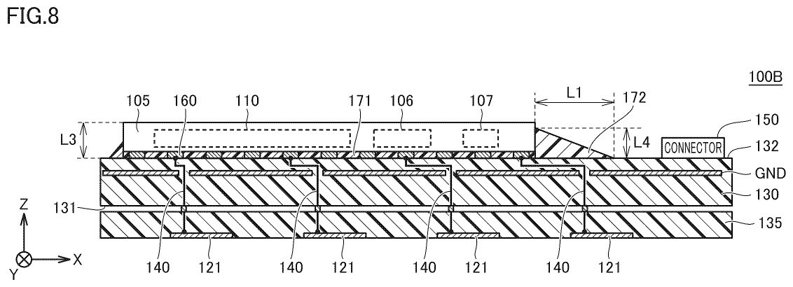

While radio frequency module 100 described above has been described to be configured to have radiating element 121 disposed in/on dielectric substrate 130, radiating element 121 is not necessarily essential to the presently disclosed radio frequency module. With reference to FIG. 8 showing a radio frequency module 100B according to a second variation, radiating element 121 may be disposed on a substrate 135 different from dielectric substrate 130, and dielectric substrate 130 and substrate 135 may be electrically interconnected. Substrate 135 may for example be a casing for communication device 10, and radio frequency module 100B may be connected to the casing with radiation element 121 thereon.

“Resin 171” and “resin 172” in the first embodiment are an example of a “first resin” and a “second resin”, respectively, in the present disclosure. “L1”, “L2”, “L3”, and “L4” in the first embodiment correspond to a “first length”, a “second length”, a “third length”, and a “fourth length”, respectively, in the present disclosure.

### Second Embodiment

In a second embodiment, a configuration to prevent resin 172 from flowing to a vicinity of connector 150 on dielectric substrate 130 will be described.

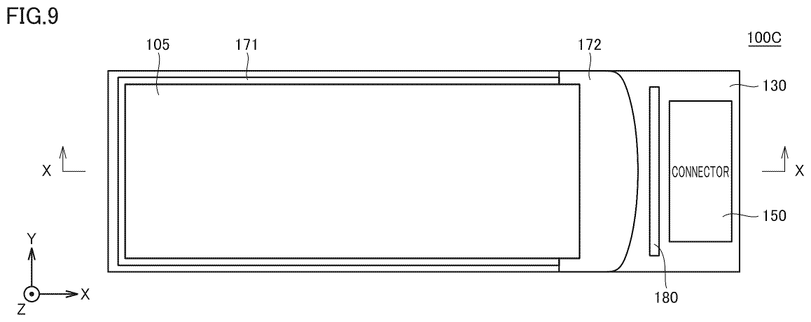

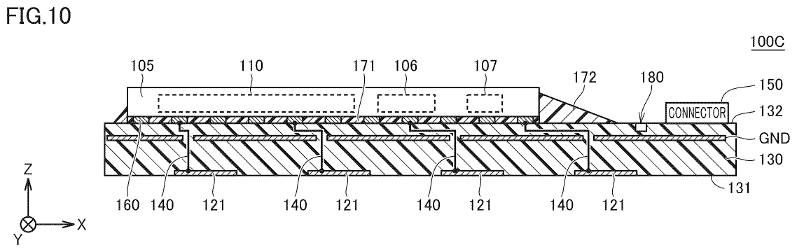

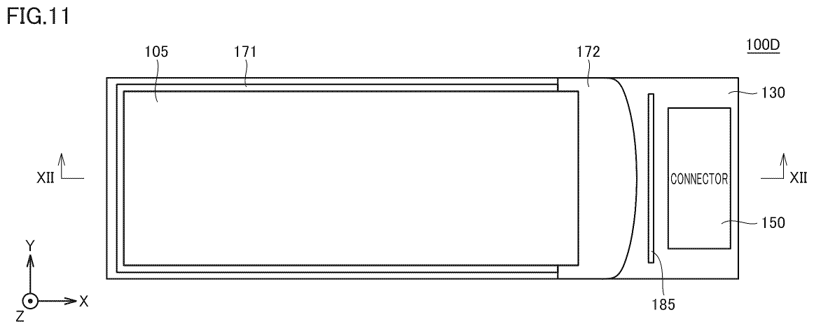

FIGS. 9 and 10 are diagrams for illustrating a radio frequency module 100C according to the second embodiment. FIG. 9 is a plan view of radio frequency module 100C. FIG. 10 is a cross-sectional perspective view taken along a line X-X of the radio frequency module 100C in FIG. 9.

Radio frequency module 100C comprises dielectric substrate 130 having upper surface 132 with a recess 180 formed therein at a position between SiP module 105 and connector 150, recess 180 extending in the direction along the Y-axis. When resin 172 is disposed on dielectric substrate 130, resin 172 flowing on the substrate is retained in recess 180, and resin 172 is thus prevented from being excessively close to connector 150.

When resin 172 is disposed to a position close to connector 150 and the radio frequency module is connected to another device using connector 150, resin 172 would interfere with a member of the other device, and the radio frequency module may be connected inappropriately. Recess 180 can define a position for an end of resin 172 in the direction along the X-axis to prevent poor connection of connector 150.

Note that recess 180 is formed on dielectric substrate 130 at a position equal to or larger than one half of and smaller than two thirds of distance L2 between SiP module 105 and connector 150, as measured from a side surface of SiP module 105, as described in the first embodiment.

### (Third Variation)

Radio frequency module 100C has been described to be configured to have a recess formed on dielectric substrate 130 to prevent a flow of resin 172 to a vicinity of connector 150. In a third variation, a configuration having a projection formed on dielectric substrate 130 to prevent a flow of resin 172 to a vicinity of connector 150 will be described.

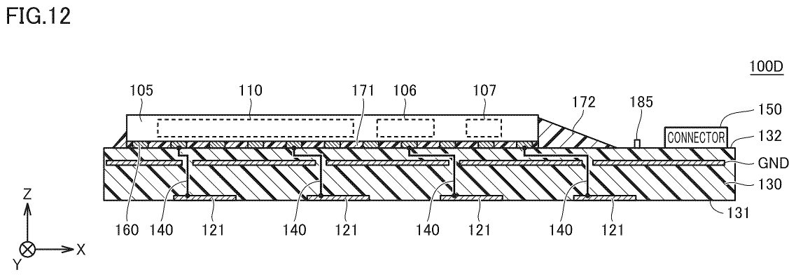

FIGS. 11 and 12 are diagrams for illustrating a radio frequency module 100D according to the third variation. FIG. 11 is a plan view of radio frequency module 100D. FIG. 12 is a cross-sectional perspective view taken along a line XII-XII of radio frequency module 100C in the FIG. 11.

Radio frequency module 100D comprises dielectric substrate 130 having upper surface 132 with a projection 185 formed thereon at a position between SiP module 105 and connector 150, projection 185 extending in the direction along the Y-axis. When resin 172 is disposed on dielectric substrate 130, resin 172 flowing on the substrate is dammed by projection 185 and thus prevented from being excessively close to connector 150.

The configuration of radio frequency module 100D also allows projection 185 to define a position for the end of resin 172 in the direction along the X-axis to prevent poor connection of connector 150. Note that the second variation and the third variation may be used together, and for example, projection 185 may be disposed in a region between recess 180 and connector 150.

### [Manufacturing Process]

Generally, manufacturing a radio frequency module employs a technique to arrange a plurality of modules on a single substrate and singulate the modules by dicing them or the like. In that case, when a resin is used to form a fillet as it is for the radio frequency module of the present embodiment, the resin would flow to another adjacent module, and the modules may be joined together by the resin.

Hereinafter a technique will be described to prevent a resin from flowing to an adjacent module in a process for manufacturing a radio frequency module.

### First Example

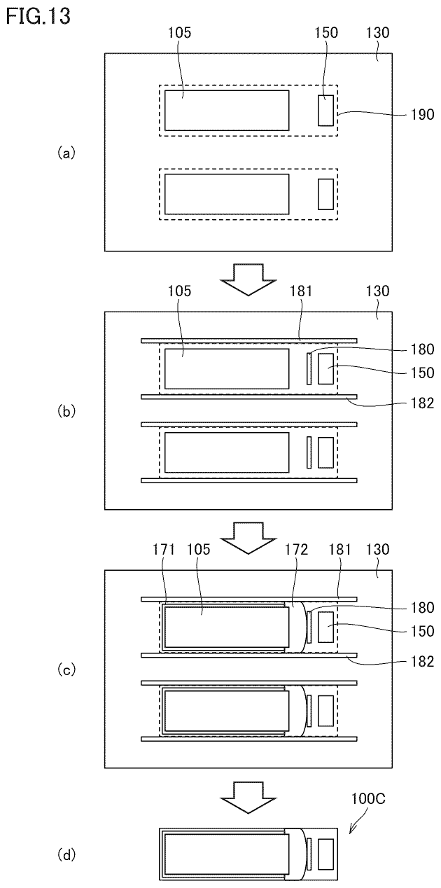

FIG. 13 is a diagram for illustrating a first example of a process for manufacturing a radio frequency module. Note that a manufacturing process of dielectric substrate 130 will not be described.

Initially, as shown in a step (a), SiP module 105 and connector 150 are mounted on dielectric substrate 130. Note that a broken line 190 in the step (a) indicates a final geometry of the radio frequency module.

Subsequently, in a step (b), recesses 181 and 182 are each formed along a portion of the radio frequency module corresponding to a longer side of dielectric substrate 130. Furthermore, as has been described in the second embodiment, recess 180 is formed between SiP module 105 and connector 150. Note that recesses 181 and 182 along the longer sides are formed to be longer than an actual length of the longer sides.

In a step (c), resin 171 is applied between SiP module 105 and dielectric substrate 130, and resin 172 is applied to a region between SiP module 105 and connector 150. At this time, recesses 180 to 182 formed in advance allow resin 172 to be retained in a predetermined region. This can prevent a flow of the resin to an adjacent module.

Subsequently, in a step (d), radio frequency module 100C is obtained by cutting a perimeter of dielectric substrate 130.

### Second Example

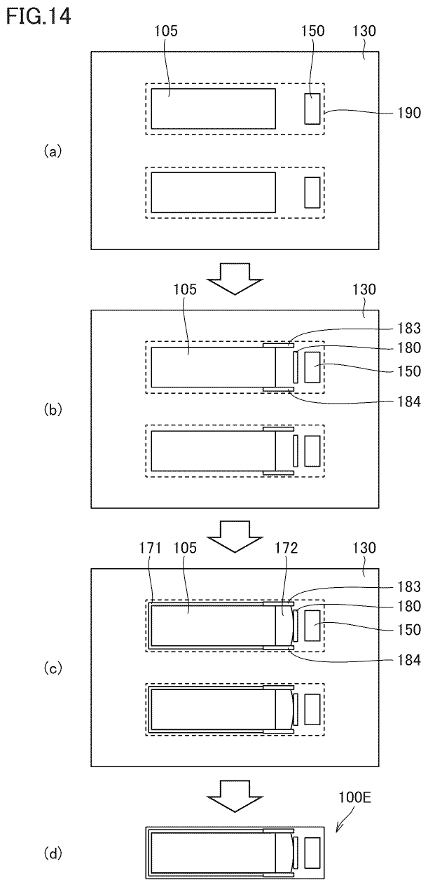

FIG. 14 is a diagram for illustrating a second example of a process for manufacturing a radio frequency module.

Initially, in a step (a), as well as that in the first example, SiP module 105 and connector 150 are mounted on dielectric substrate 130.

Subsequently, in a step (b), recess 180 is formed between SiP module 105 and connector 150, and recesses 183 and 184 are formed along longer sides of dielectric substrate 130 in a region between SiP module 105 and the longer sides, respectively. Recesses 183 and 184 are not formed along the entirety of the longer sides of dielectric substrate 130; rather, the recesses are each formed only at the portion of a region to which resin 172 is to be applied.

In a step (c), resin 171 is applied between SiP module 105 and dielectric substrate 130, and resin 172 is applied in a region between SiP module 105 and connector 150. This process also allows resin 172 to be retained in a region surrounded by recesses 180, 183 and 184 and SiP module 105, and can thus prevent a flow of the resin to an adjacent module.

Subsequently, in a step (d), a radio frequency module 100E is obtained by cutting a perimeter of dielectric substrate 130.

While the manufacturing processes of the first and second examples have been described for forming a recess, the recess may be replaced with a projection, as described in the third variation. Furthermore, the recess and the projection are not limited to a configuration in which only one of the recess and the projection is used, and the recess and the projection may both be used. For example, the recess and the projection may be formed in parallel, or may be switched as desired, and thus selected and formed depending on the location.

### [Aspects]

It will be understood by those skilled in the art that the exemplary embodiments described above are specific examples of the following aspects.

(Clause 1) In one aspect, a radio frequency module is configured to feed a radiating element with a radio frequency signal. The radio frequency module comprises a dielectric substrate in the form of a flat plate, an electronic circuit, a connector, a first resin, and a second resin. The dielectric substrate has a first surface and a second surface. The electronic circuit is mounted on the second surface of the dielectric substrate and configured to feed the radiating element with a radio frequency signal. The connector is mounted on the second surface and connectable to an external device. The dielectric substrate is generally in the form of a rectangle having a longer side and a shorter side when viewed in a plan view in a direction along a normal to the dielectric substrate. The connector is spaced from the electronic circuit in a first direction along the longer side. The first resin is disposed between the dielectric substrate and the electronic circuit. The second resin is disposed on the second surface in a region between the electronic circuit and the connector and covers a side surface of the electronic circuit facing the connector. When the second resin has a first length from the electronic circuit to an end of the second resin in the first direction and a distance between the electronic circuit and the connector is represented as a second length, the first length is equal to or larger than one half of the second length.

(Clause 2) The radio frequency module according to clause 1, wherein the first length is smaller than two thirds of the second length.

(Clause 3) The radio frequency module according to clause 1, wherein when the electronic circuit has a maximum height from the second surface as a third length, the first length is larger than 1.0 times and smaller than 1.4 times the third length.

(Clause 4) The radio frequency module according to clause 1, wherein when the second resin has a portion in contact with the electronic circuit with a maximum length in the direction along the normal to the dielectric substrate as a fourth length, the first length is larger than 1.0 times and smaller than 7.0 times the fourth length.

(Clause 5) The radio frequency module according to any one of clauses 1 to 4, wherein the second surface between the end of the second resin in the first direction and the connector has a recess extending in a second direction intersecting the first direction.

(Clause 6) The radio frequency module according to any one of clauses 1 to 4, wherein the second surface between the end of the second resin in the first direction and the connector has a projection extending in a second direction intersecting the first direction.

(Clause 7) The radio frequency module according to any one of clauses 1 to 6, wherein the second resin does not extend beyond the longer side of the dielectric substrate.

(Clause 8) The radio frequency module according to any one of clauses 1 to 7, wherein the radiating element is disposed closer to the first surface of the dielectric substrate than the second surface of the dielectric substrate.

It should be understood that the embodiments disclosed herein are illustrative and non-restrictive in any respect. The scope of the present invention is defined by the terms of the claims rather than by the foregoing description of the embodiments, and is intended to encompass any modification falling within the meaning and scope equivalent to the terms of the claims.

### REFERENCE SIGNS LIST

10 communication device, 100-100E radio frequency module, 105 SiP module, 106 PMIC, 10π electronic element, 110 RFIC, 111A-111D, 113A-113D and 117 switch, 112AR-112DR low noise amplifier, 112AT-112DT power amplifier, 114A-114D attenuator, 115A-115D phase shifter, 116 signal combining/dividing device, 118 mixer, 119 amplifier circuit, 120 antenna device, 121 radiating element, 130 dielectric substrate, 131, 132 major surface, 135 substrate, 140 feed line, 150 connector, 160 solder bump, 171, 172, 172A resin, 180-184 recess, 185 projection, 200 BBIC, GND ground electrode, S1, S2 supporting point.

1. A radio frequency module configured to feed a radiating element with a radio frequency signal, the radio frequency module comprising:
a dielectric substrate in a form of a flat plate having a first surface and a second surface;
an electronic circuit mounted on the second surface of the dielectric substrate and configured to feed the radiating element with a radio frequency signal;
a connector mounted on the second surface and connectable to an external device, the dielectric substrate being generally in a form of a rectangle having a longer side and a shorter side when viewed in a plan view in a direction along a normal to the dielectric substrate, the connector being spaced from the electronic circuit in a first direction along the longer side;
a first resin disposed between the dielectric substrate and the electronic circuit; and
a second resin disposed on the second surface in a region between the electronic circuit and the connector and covering a side surface of the electronic circuit facing the connector, wherein
the second resin functions as a fillet; and
when the second resin has a first length from the electronic circuit to an end of the second resin in the first direction and a distance between the electronic circuit and the connector is represented as a second length, the first length is equal to or larger than one half of the second length.

2. The radio frequency module according to claim 1, wherein the first length is smaller than two thirds of the second length.

3. The radio frequency module according to claim 1, wherein when the electronic circuit has a maximum height from the second surface as a third length, the first length is larger than 1.0 times and smaller than 1.4 times the third length.

4. The radio frequency module according to claim 1, wherein when the second resin has a portion in contact with the electronic circuit with a maximum length in the direction along the normal to the dielectric substrate as a fourth length, the first length is larger than 1.0 times and smaller than 7.0 times the fourth length.

5. The radio frequency module according to claim 1, wherein the second surface between the end of the second resin in the first direction and the connector has a recess extending in a second direction intersecting the first direction.

6. The radio frequency module according to claim 1, wherein the second surface between the end of the second resin in the first direction and the connector has a projection extending in a second direction intersecting the first direction.

7. The radio frequency module according to claim 1, wherein the second resin does not extend beyond the longer side of the dielectric substrate.

8. The radio frequency module according to claim 1, wherein the radiating element is disposed closer to the first surface of the dielectric substrate than the second surface of the dielectric substrate.

9. The radio frequency module according to claim 1, wherein when a maximum height of the electronic circuit from the second surface is represented as a third length and a maximum height of a portion of the second resin in contact with the electronic circuit from the second surface is represented as a fourth length, the third length is larger than the fourth length.

10. The radio frequency module according to claim 1, wherein the electronic circuit has a first side surface and a second side surface opposite to the first side surface, the second side surface being in contact with the second surface, the first side surface is not covered with the second resin.

11. The radio frequency module according to claim 1, wherein the first resin is an underfill material configured to fill a gap between the electronic circuit and the dielectric substrate.

12. The radio frequency module according to claim 1, wherein the second resin is a thermosetting resin.

13. The radio frequency module according to claim 1, wherein the second resin contains a filler.

14. The radio frequency module according to claim 1, wherein the radiating element is disposed on a separate substrate that is electrically interconnected with the dielectric substrate.

15. A communication device, comprising:
a radio frequency module according to claim 1; and
a baseband signal processing circuit electrically coupled to the connector of the radio frequency module.

16. The communication device according to claim 15, wherein the communication device is one of a mobile phone, a smartphone, a tablet, or a personal computer.

17. A method for manufacturing a radio frequency module, the method comprising:
mounting an electronic circuit on a second surface of a dielectric substrate;
mounting a connector on the second surface of the dielectric substrate, wherein the connector is spaced from the electronic circuit by a second length (L2);
disposing a first resin between the dielectric substrate and the electronic circuit; and
disposing a second resin on the second surface in a region between the electronic circuit and the connector, the second resin covering a side surface of the electronic circuit facing the connector,
wherein the second resin extends a first length (L1) from the electronic circuit, and the first length (L1) is equal to or larger than one half of the second length (L2).

18. The method according to claim 17, further comprising:
forming a recess in the second surface between the electronic circuit and the connector prior to disposing the second resin,
wherein the recess is configured to retain the second resin and prevent the second resin from flowing to a vicinity of the connector.

19. The method according to claim 17, further comprising:
forming a projection on the second surface between the electronic circuit and the connector prior to disposing the second resin,
wherein the projection is configured to dam the second resin and prevent the second resin from flowing to a vicinity of the connector.

20. The method according to claim 17, wherein the step of disposing the second resin comprises applying the second resin to extend the first length (L1) to be smaller than two thirds of the second length (L2).
